(19) United States
(12) Patent Application Publication
(10) Pub. No.: US 2024/0275499 A1
(43) Pub. Date: Aug. 15, 2024

(54) CENTRALIZED CONTROL OF AN AUTOMATED TEST EQUIPMENT SYSTEM USING COMMERCIAL OFF-THE-SHELF SERVERS

(71) Applicant: Rakuten Symphony UK Ltd, Surrey (GB)

(72) Inventors: Hugh Roger McCalman, Surrey (GB); Stephen Hedges, Surrey (GB)

(73) Assignee: Rakuten Symphony UK Ltd, Surrey (GB)

(21) Appl. No.: 18/017,568

(22) PCT Filed: Jul. 11, 2022
(86) PCT No.: PCT/US22/36654

§ 371 Date: Jan. 23, 2023

(51) Int. Cl. H04B 17/00; G01R 31/28

(52) U.S. Cl. CPC H04B 17/0085; G01R 31/2834

(57) ABSTRACT

An ATE system may include accessing, by a test control apparatus, a centralized server via a single connection, where an operating system of the ATE, a test sequence editor, test sequences, data base for all test sequence results, and parameters for one or more Device Under Test (DUT) may reside on the centralized server. The ATE system may include accessing by the test control apparatus the one or more DUT of the ATE system via the centralized server, the centralized server having one or more end-to-end connections with the one or more DUT. The ATE system may include accessing, by the test control apparatus, test data from the one or more DUT via the single connection to the centralized server, where the centralized server provides the test control apparatus with access to all of the one or more DUT and all of the test data from the one or more DUT.

### TECHNICAL FIELD

In some example embodiments, the subject matter herein generally relates to Automated Test Equipment (ATE) systems, and in particular to centralized control and management of these systems.

### BACKGROUND

An ATE system is typically computer based equipment that automates traditional manual electronic test equipment and processes with a goal of minimizing human interaction. End devices under test may be referred to as a Device Under Test (DUT), a Unit Under Test (UUT) or Equipment Under Test (EUT). It should be understood that the terms DUI, UUT, and EUT may be used interchangeably and refer to an end device under test.

Recent market data estimates that the global ATE market size is valued close to USD 7 billion and is expected to expand at an annual growth rate of 3.3% through 2028.

Significant increases in the number of connected devices as well as consumer electronics coupled with increased focus on quality improvement and end-to-end testing solutions is expected to further drive the ATE market.

ATE implementation in a manufacturing environment allows manufacturers to enhance performance, increase production, and reduce costs. Designing an ATE system with Commercial-Off-the-Shelf (COTS) servers and open source software reduces the cost of the ATE system.

A problem exists, however, in that the use of COTS servers and open source software does not provide centralized control and management of the ATE system. That is, there is no centralized control of software code for the ATE operating system, one or more DUTs, test sequence editor, and test sequences of the ATE system. Thus, the need exists for a centralized control solution of an ATE system designed with COTS servers and open source software.

### SUMMARY

In one aspect, a method may include accessing by a test control apparatus a centralized server via a single connection, where an operating system of the ATE, a test sequence editor, test sequences, data base for all test sequence results, and parameters for one or more Device Under Test (DUT) reside on the centralized server. The method may include accessing by the test control apparatus the one or more DUT system via the centralized server, the centralized server having one or more end-to-end connections with the one or more DUT. The method may furthermore include accessing by the test control apparatus test data from the one or more DUT via the single connection to the centralized server, where the centralized server provides the test control apparatus with access to all of the one or more DUT and all of the test data from the one or more DUT.

Implementations may include one or more of the following features. The method may further comprise accessing by the test control apparatus the one or more DUT of the ATE system via one or more Local Area Networks (LANs), the one or more LANs coupling the one or more DUT with the centralized server.

The method where the centralized server is a Commercial-Off-the-Shelf (COTS) server. The method where the test control apparatus connects to the centralized server via at least one of a wired or wireless connection. The method where the test control apparatus is at least one of a stationary computing apparatus, a laptop computing apparatus, and a mobile computing apparatus. The method where the test control apparatus is connected to the centralized server via a secured connection. The method where the test control apparatus is configured to update software code for at least one of the ATE operating system, the one or more DUT, the test sequence editor, and the test sequences of the ATE system.

The method may include verifying design testing in a lab environment. The method may include one or more portable test servers configured to run a copy of the centralized server enabling the test control apparatus to connect to the one or more portable test servers and perform off-site testing. The method where the test control apparatus accesses the centralized server via a web based interface. Implementations of the described techniques may include hardware, a method or process, or a computer tangible medium.

In another aspect, an Automated Test Equipment (ATE) system may include one or more Device Under Test (DUT). The ATE system may also include a centralized server configured to establish a connection with the one or more DUT via one or more end-to-end connections with the one or more DUT. The ATE system may furthermore include a test control apparatus configured to establish a connection with the centralized server via a single connection, where an operating system of the ATE, a test sequence editor, test sequences, data base for all test sequence results, and DUT parameters reside on the centralized server, and where the centralized server provides the test control apparatus with access to all of the one or more DUT and all of the test data from the one or more DUT. Other embodiments of this aspect include corresponding computer systems, apparatus, and computer programs recorded on one or more computer storage devices, each configured to perform the actions of the methods.

Implementations may include one or more of the following features. The ATE system where the centralized server is a Commercial-Off-the-Shelf (COTS) server. The ATE system where test control apparatus connects to the centralized server via at least one of a wired or wireless connection. The ATE system where the test control apparatus is at least one of a stationary computing apparatus, a laptop computing apparatus, and a mobile computing apparatus. The ATE system where the test control apparatus is connected to the centralized server via a secured connection. For example, a virtual private network (VPN) may be used to establish a secure connection.

The ATE system where the test control apparatus is configured to update software code for at least one of the ATE operating system, the one or more DUT, the test sequence editor, and the test sequences of the ATE system. The ATE system where the ATE system is configured to perform design verification testing in a lab. The ATE system further comprising one or more portable test servers configured to run a copy of the centralized server enabling the test control apparatus to connect to the one or more portable test servers and perform off-site testing. The ATE system where the test control apparatus accesses the centralized server via a web based interface. The ATE system further comprising one or more Local Area Networks (LANs) where the one or more LANs couple the one or more DUT with the centralized server.

Other embodiments of this aspect include corresponding computer systems, apparatus, and computer programs recorded on one or more computer storage devices, each configured to perform the actions of the methods.

### BRIEF DESCRIPTION OF THE DRAWINGS

In the following drawings:

FIG. 1A is a diagram of an exemplary ATE system according to an embodiment;

FIG. 1B is a diagram of an exemplary ATE system according to an embodiment;

FIG. 2 is a flowchart representing a process of centralized control of an ATE system according to some embodiments;

FIG. 3 is a flowchart representing a process of centralized control of an ATE system according to some further embodiments; and

FIG. 4 is a diagram of an ATE system according to some embodiments

### DETAILED DESCRIPTION

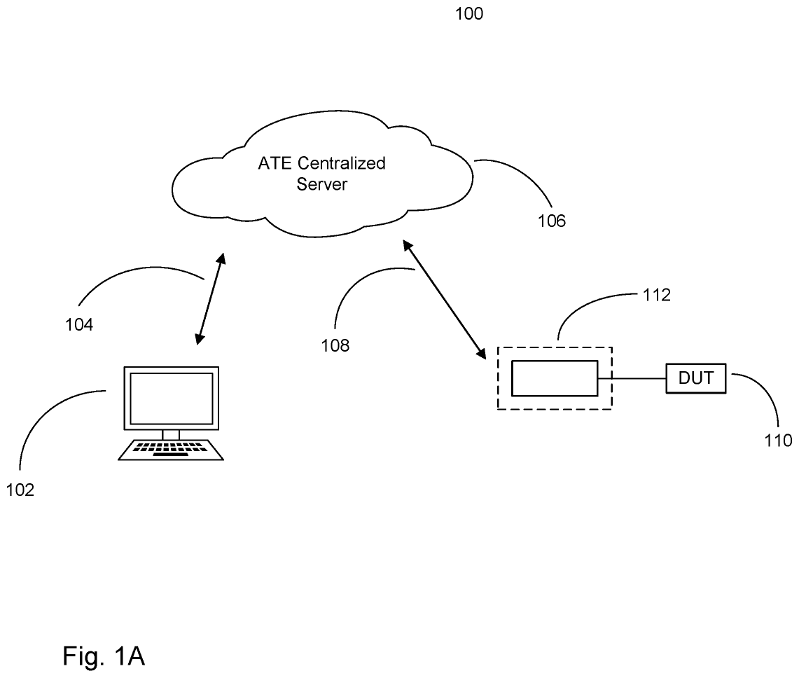

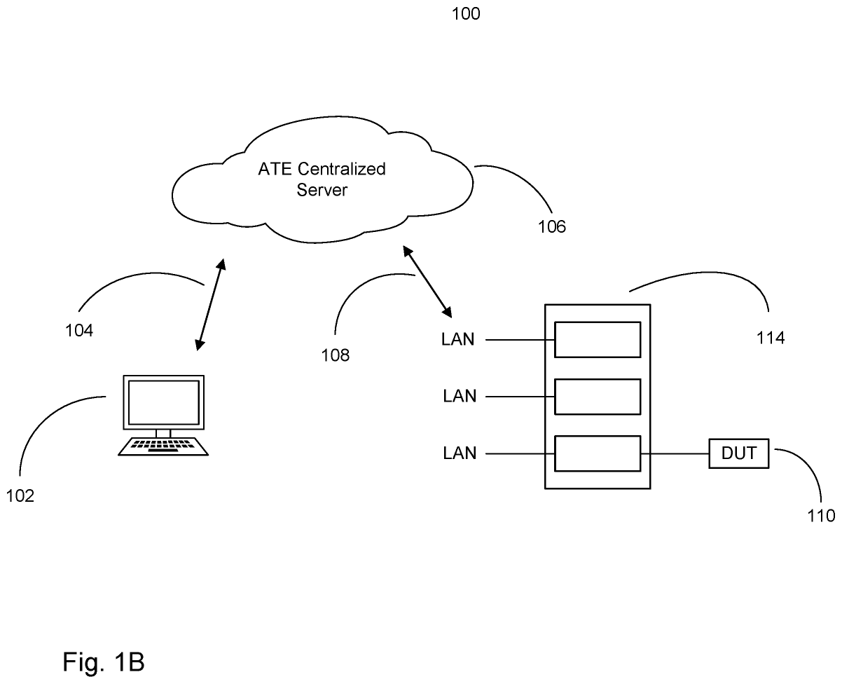

FIG. 1A illustrates an ATE system 100 including a test control apparatus 102, a centralized server 106, and DUT 110 where the centralized server 106 may be a COTS server. The ATE system may include an optional network interface 112. The test control apparatus 102 may be a stationary computer, a laptop computer, or a mobile computing device such as a tablet computing device. Test control apparatus 102 may be connected to the centralized server 106 via a wired connection or a wireless connection 104 where the wired or wireless connection 104 is a single connection to the centralized server 106.

A least one of: an operating system of the ATE, a test sequence editor, test sequences, data base for all test sequence results, and parameters for one or more DUT may reside on the centralized server 106 alone or in any combination.

The centralized server 106 is coupled to the one or more DUT 110 via link 108. The centralized server 106 may be directly coupled with the one or more DUT 110 via link 108 where link 108 establishes one or more end-to-end connections between the one or more DUT 110 and the centralized server 106. Optionally, the centralized COTS server 106 may be coupled with the one or more DUT through a network interface 112. The centralized server 106 may connect with the network interface 112 via link 108, and the network interface 112 may directly connect with the DUT 110.

FIG. 1B is similar to FIG. 1A. FIG. 1B illustrates an aspect of the ATE system where one or more LANs 114 replace the network interface 112 shown in FIG. 1A. In FIG. 1B, the centralized server 106 is configured to connect to the one or more DUT 110 via the one or more LANs 114. The one or more DUT 110 may be connected to the one or more LANs. Although the illustration in FIG. 1B shows three LANs and one DUT connected to a single LAN, it should be understood that more than one DUT can be connected to a single LAN, and multiple LANs can connect to multiple DUT. In other words, the concepts described in the disclosure are not limited to a single DUT nor to three LANs.

Thus, FIG. 1B should be understood to illustrates a scalable solution such that a test control apparatus 102 may access a diverse number of DUT in a large distributed ATE system via the single connection 108 with the centralized server 106.

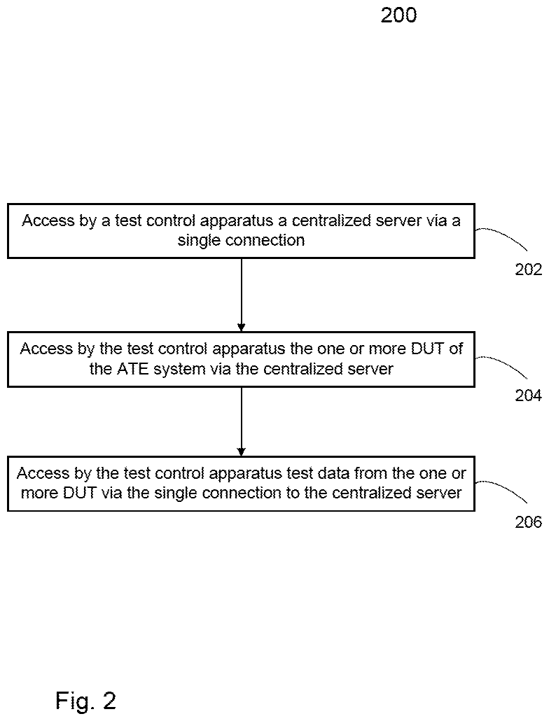

FIG. 2 is a flowchart representing a process of centralized control of an ATE system. Process 200 may include accessing by a test control apparatus a centralized server via a single connection at 202. For example, the test control apparatus may access the centralized server via a single connection, where an operating system of the ATE, a test sequence editor, test sequences, data base for all test sequence results, and parameters for one or more DUT reside on the centralized server, as described above. As also shown in FIG. 2, process 200 may include accessing by the test control apparatus the one or more DUT of the ATE system via the centralized server at 204, the centralized server having one or more end-to-end connections with the one or more DUT. For example, the test control apparatus may access the the one or more DUT via the centralized server, the centralized server having one or more end-to-end connections with the one or more DUT, as described above. As further shown in FIG. 2, process 200 may include accessing, by the test control apparatus, test data from the one or more DUT via the single connection to the centralized server, where the centralized server provides the test control apparatus with access to all of the one or more DUT and all of the test data from the one or more DUT 206. For example, the test control apparatus may access test data from the one or more DUT via the single connection to the centralized server, where the centralized server provides the test control apparatus with access to all of the one or more DUT and all of the test data from the one or more DUT, as described above.

Although FIG. 2 shows example blocks of process 200, in some implementations, process 200 may include additional blocks, fewer blocks, different blocks, or differently arranged blocks than those depicted in FIG. 2. Additionally, or alternatively, two or more of the blocks of process 200 may be performed in parallel.

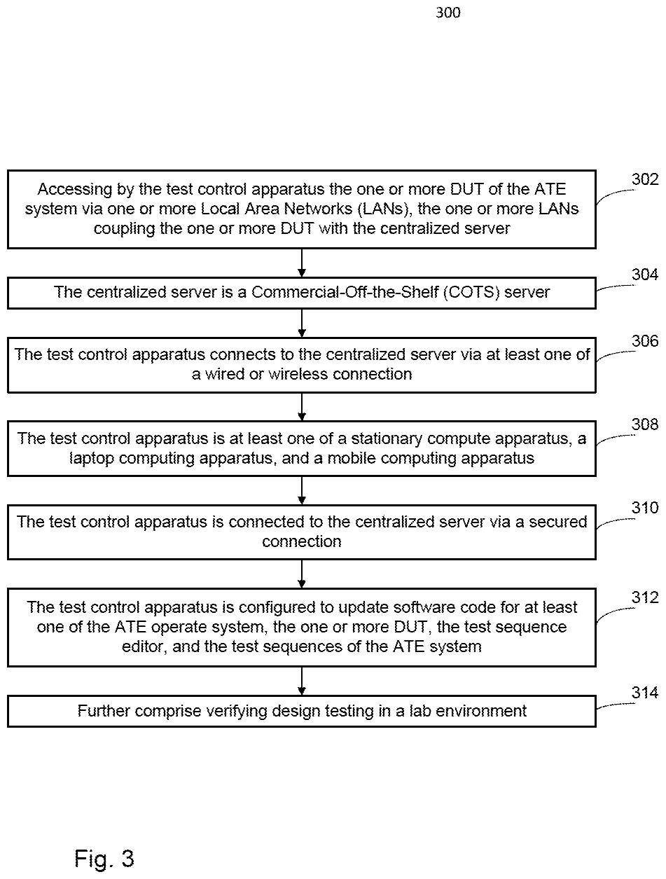

FIG. 3 is a flowchart of a process 300 according to further embodiments of the present disclosure. According to an example, one or more process blocks of FIG. 3 may be performed by ATE system.

Process 300 may include additional implementations, such as any single implementation or any combination of implementations described below and/or in connection with one or more other processes described elsewhere herein. In a first implementation, process 300 may include accessing by the test control apparatus the one or more DUT of the ATE system via one or more Local Area Networks (LANs), the one or more LANs coupling the one or more DUT with the centralized server.

In a second implementation, alone or in combination with the first implementation, the centralized server is a Commercial-Off-the-Shelf (COTS) server.

In a third implementation, alone or in combination with the first and second implementation, the test control apparatus connects to the centralized server via a wired or wireless connection.

In a fourth implementation, alone or in combination with one or more of the first through third implementations, the test control apparatus is at least one of a stationary computing apparatus, a laptop computing apparatus, and a mobile computing apparatus.

In a fifth implementation, alone or in combination with one or more of the first through fourth implementations, the test control apparatus is connected to the centralized server via a secured connection.

In a sixth implementation, alone or in combination with one or more of the first through fifth implementations, the test control apparatus is configured to update software code for at least one of the ATE operating system, the one or more DUT, the test sequence editor, and the test sequences of the ATE system.

A seventh implementation, alone or in combination with one or more of the first through sixth implementations, may include verifying design testing in a lab environment.

An eighth implementation, alone or in combination with one or more of the first through seventh implementations, may include one or more portable test servers configured to run a copy of the centralized server enabling the test control apparatus to connect to the one or more portable test servers and perform off-site testing.

In a ninth implementation, alone or in combination with one or more of the first through eighth implementations, the test control apparatus accesses the centralized server via a web based interface. Thus, the test control apparatus, for example a laptop computer using a commercial web browser, may access the centralized server. The web browser may include a Graphical User Interface (GUI) with pull down menus to select the DUT and test sequence to run, for example.

It should be noted that while FIG. 3 shows example blocks of process 300, in some implementations, process 300 may include additional blocks, fewer blocks, different blocks, or differently arranged blocks than those depicted in FIG. 3. Additionally, or alternatively, two or more of the blocks of process 300 may be performed in parallel.

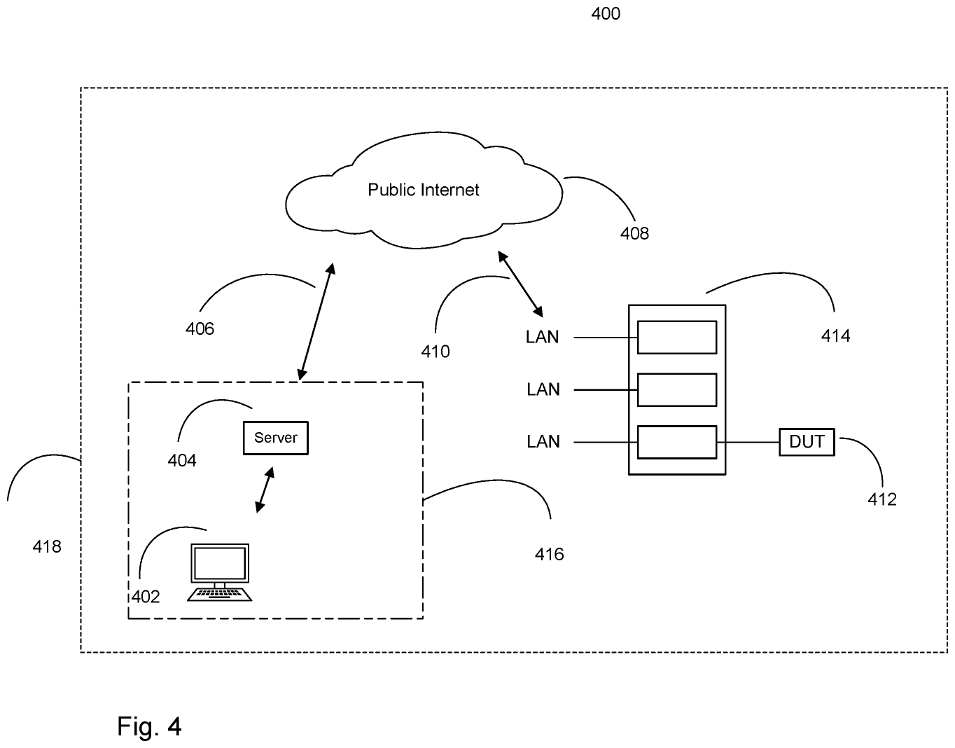

FIG. 4 illustrates an ATE system according to some embodiments. ATE system 400 includes a test control apparatus 402, A portable server 404 configured to run a copy of a centralized server, such as the centralized server illustrated in FIG. 1 at 106, one or more LANs 414 and one or more DUT 412.

A least one of: an operating system of the ATE, a test sequence editor, test sequences, data base for all test sequence results, and parameters for one or more DUT may reside on the portable server 404 alone or in any combination. The test control apparatus 402, which may be a stationary computer, a laptop computer, or a mobile computing device such as a tablet computing device, is connected to the portable server 404. The portable server 404 is connected to a public internet 408 via a communication link 406, which may be a wired or wireless connection. The portable server 404 and the test control apparatus 402 may be located at a remote location 416.

The one or more LANs 414 are connected to the public internet 408 via communication link 410, and the one or more DUT 412 are coupled in the one or more LANs 414. The network created using the public internet may be a secured network 418. By using a VPN a secured network 418 is established from the public internet 408 connection. Thus, a remote user can perform all of the ATE system functions from a remote location using a secure network. It should be understood that present disclosure is not limited to a VPN, and other applications and methods may be used to establish a secure network. For, example VPN, open wireless router (OpenWrt), the onion router (Tor), Silo, Whonix, Tails, and the like may be used alone or in combination to establish a secure network.

While aspects of the disclosure have been illustrated and described in detail in the drawings and foregoing description, such illustrations and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims.

In the claims, the word “comprising” does not exclude other elements or steps, and the indefinite article “a” or “an” does not exclude a plurality.

A single processor, device or other unit may fulfill the functions of several items recited in the claims. The mere fact that certain measures are recited in mutually different dependent claims does not indicate that a combination of these measures cannot be used to advantage.

Operations like acquiring, accessing, determining, obtaining, outputting, providing, store or storing, calculating, simulating, receiving, warning, and stopping can be implemented as program code means of a computer program and/or as dedicated hardware.

A computer program may be stored and/or distributed on a suitable medium, such as an optical storage medium or a solid-state medium, supplied together with or as part of other hardware, but may also be distributed in other forms, such as via the Internet or other wired or wireless telecommunication systems.

1. A method of centralized control of an Automated Test Equipment (ATE) system, the method comprising:
accessing by a test control apparatus a centralized server via a single connection, wherein an operating system of the ATE, a test sequence editor, test sequences, data base for all test sequence results, and parameters for one or more Device Under Test (DUT) reside on the centralized server;
accessing by the test control apparatus the one or more DUT of the ATE system via the centralized server, the centralized server having one or more end-to-end connections with the one or more DUT; and
accessing by the test control apparatus test data from the one or more DUT via the single connection to the centralized server, wherein the centralized server provides the test control apparatus with access to all of the one or more DUT and all of the test data from the one or more DUT.

2. The method of claim 1, further comprising accessing by the test control apparatus the one or more DUT of the ATE system via one or more Local Area Networks (LANs), the one or more LANs coupling the one or more DUT with the centralized server.

3. The method of claim 1, wherein the centralized server is a Commercial-Off-the-Shelf (COTS) server.

4. The method according to claim 1, wherein the test control apparatus connects to the centralized server via at least one of a wired or wireless connection.

5. The method according to claim 4, wherein the test control apparatus is at least one of a stationary computing apparatus, a laptop computing apparatus, and a mobile computing apparatus.

6. The method according to claim 4, wherein the test control apparatus is connected to the centralized server via a secured connection.

7. The method according to claim 1, wherein the test control apparatus is configured to update software code for at least one of the ATE operating system, the one or more DUT, the test sequence editor, and the test sequences of the ATE system.

8. The method according to claim 1, further comprising verifying design testing in a lab environment.

9. The method of claim 1, further comprising one or more portable test servers configured to run a copy of the centralized server enabling at least the test control apparatus to connect to the one or more portable test servers and perform off-site testing.

10. The method of claim 1, wherein the test control apparatus accesses the centralized server via a web based interface.

11. An Automated Test Equipment (ATE) system comprising:
one or more Device Under Test (DUT);
a centralized server configured to establish a connection with the one or more DUT via one or more end-to-end connections with the one or more DUT; and
a test control apparatus configured to establish a connection with the centralized server via a single connection, wherein an operating system of the ATE, a test sequence editor, test sequences, data base for all test sequence results, and DUT parameters reside on the centralized server, and wherein the centralized server provides the test control apparatus with access to all of the one or more DUT and all of the test data from the one or more DUT.

12. The ATE system of claim 11, wherein the centralized server is a Commercial-Off-the-Shelf (COTS) server.

13. The ATE system of claim 11, wherein test control apparatus connects to the centralized server via at least one of a wired or wireless connection.

14. The ATE system of claim 13, wherein the test control apparatus is at least one of a stationary computing apparatus, a laptop computing apparatus, and a mobile computing apparatus.

15. The ATE system of claim 13, wherein the test control apparatus is connected to the centralized server via a secured connection.

16. The ATE system of claim 11, wherein the test control apparatus is configured to update software code for at least one of the ATE operating system, the one or more DUT, the test sequence editor, and the test sequences of the ATE system.

17. ATE system of claim 11, wherein the ATE system is configured to perform design verification testing in a lab.

18. The ATE system of claim 11, further comprising one or more portable test servers configured to run a copy of the centralized server enabling at least the test control apparatus to connect to the one or more portable test servers and perform off-site testing.

19. The ATE system of claim 11, wherein the test control apparatus accesses the centralized server via a web based interface.

20. The ATE system of claim 11, further comprising one or more Local Area Networks (LANs), wherein the one or more LANs couple the one or more DUT with the centralized server.
